(19) United States
(12) Patent Application Publication
(10) Pub. No.: US 2024/0429148 A1
(43) Pub. Date: Dec. 26, 2024

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Yuki YANO, Tokyo (JP); Tsuyoshi MATSUOKA, Tokyo (JP)

(73) Assignee: Mitsubishi Electric Corporation, Tokyo (JP)

(21) Appl. No.: 18/696,262

(22) PCT Filed: Dec. 15, 2021
(86) PCT No.: PCT/JP2021/046236

§ 371 Date: Mar. 27, 2024

(51) Int. Cl. H01L 23/498; H01L 21/48; H01L 23/00; H01L 25/065

(52) U.S. Cl. CPC H01L 23/49822; H01L 21/4857; H01L 23/49838; H01L 24/27; H01L 24/32; H01L 24/29; H01L 25/0655; H01L 2224/2732; H01L 2224/29144; H01L 2224/29155; H01L 2224/32225; H01L 2924/3512

(57) ABSTRACT

An object of the present disclosure is to suppress damage to or occurrence of cracks on an upper surface of a semiconductor element when a bonding material for connecting a metal lead electrode to a semiconductor element is supplied onto the semiconductor element by screen printing. According to the present disclosure, a semiconductor device (101) includes a plurality of semiconductor elements (1), an insulating substrate (2) having a mounting area (2a1) where the plurality of semiconductor elements (1) are mounted on an upper surface thereof and a non-mounting area (2a2) protruding upward from the mounting area (2a1) and where no plurality of semiconductor elements (1) are mounted, and a metal lead electrode (4) bonded to an upper surface of each of the semiconductor elements (1) with a bonding material (3a), in which a difference in height between the mounting area (2a1) and the non-mounting area (2a2) is greater than or equal to a thickness of each of the semiconductor elements (1).

### TECHNICAL FIELD

The present disclosure relates to a semiconductor device having a metal lead electrode.

### BACKGROUND ART

In a semiconductor device such as a power semiconductor device, there is a method for making a circuit connection between the semiconductor element and an external electrode by directly bonding the semiconductor element to metal lead electrodes without using metal wire bonding in the main current path (for example, see Patent Document 1). According to the method, a large current, a long life, and high reliability of the semiconductor device can be materialized.

To directly bond the semiconductor element to a metal lead electrode, a bonding material, such as paste solder, needs to be supplied onto the semiconductor element. As methods therefor, there are dispensing supply and supply through screen printing.

### PRIOR ART DOCUMENTS

### Patent Document(s)

[Patent Document 1] International Publication No. 2020/039986

### SUMMARY

### Problem to be Solved by the Invention

With dispensing supply, the dispense coating is conducted to each semiconductor element one by one, posing the problem of taking time when there are a number of semiconductor elements. Further, if the supply of the bonding material varies for each semiconductor element, it may lead to tilting of the metal lead electrode, resulting in a problem of poor bonding between the metal lead electrode and the semiconductor element.

Whereas, with screen printing, there is a problem in that an upper surface of the semiconductor element is damaged due to direct contact of the metal mask onto the semiconductor element. Further, a problem is posed that when the squeegee passes over the metal mask, stress is applied to the semiconductor element, causing cracks and resulting in poor characteristics.

The technique of the present disclosure is made to solve the above-mentioned problems, and an object thereof is to suppress damage to or occurrence of cracks on the upper surface of the semiconductor element when a bonding material for connecting a metal lead electrode to a semiconductor element is supplied onto the semiconductor element by screen printing.

### Means to Solve the Problem

According to the present disclosure, a semiconductor device includes a plurality of semiconductor elements, an insulating substrate having, on its upper surface, a mounting area where the plurality of semiconductor elements are mounted and a non-mounting area protruding upward from the mounting area and where the plurality of semiconductor elements are not mounted, and a metal lead electrode bonded to an upper surface of each of the semiconductor elements with a bonding material, in which a difference in height between the mounting area and the non-mounting area is greater than or equal to a thickness of each of the semiconductor elements.

### Effects of the Invention

According to the semiconductor device of the present disclosure, when the bonding material is supplied to each semiconductor element by screen printing in the manufacturing process, a gap is created between the metal mask and each semiconductor element. Therefore, the bonding material can be stably and collectively supplied to the upper surface of each semiconductor clement by screen printing without damaging the upper surface of each semiconductor element. Therefore, the semiconductor device of the present disclosure is a semiconductor device that is stable, has a long life, and can be manufactured with high productivity. The objects, features, aspects, and advantages of the present disclosure will become more apparent from the following detailed description and the accompanying drawings.

### BRIEF DESCRIPTION OF DRAWINGS

FIG. 1 A cross-sectional view of a semiconductor device according to Embodiment 1.

FIG. 2 A flowchart illustrating manufacturing processes of the semiconductor device according to Embodiment 1.

FIG. 3 A cross-sectional view illustrating a manufacturing process of the semiconductor device according to Embodiment 1.

FIG. 4 A cross-sectional view illustrating a manufacturing process of the semiconductor device according to Embodiment 1.

FIG. 5 A cross-sectional view illustrating a manufacturing process of the semiconductor device according to Embodiment 1.

FIG. 6 A cross-sectional view illustrating a manufacturing process of the semiconductor device according to Embodiment 1.

FIG. 7 A cross-sectional view illustrating a manufacturing process of the semiconductor device according to Embodiment 1.

FIG. 8 A cross-sectional view of a semiconductor device according to Embodiment 2.

FIG. 9 A cross-sectional view of a semiconductor device according to Embodiment 3.

FIG. 10 A cross-sectional view of a semiconductor device according to Embodiment 4.

FIG. 11 A cross-sectional view illustrating a manufacturing process of the semiconductor device according to Embodiment 4.

FIG. 12 A cross-sectional view illustrating a manufacturing process of the semiconductor device according to Modification of Embodiment 4.

### DESCRIPTION OF EMBODIMENT(S)

### A. Embodiment 1

### A-1. Configuration

FIG. 1 is a cross-sectional view of a semiconductor device 101 according to Embodiment 1. The semiconductor device 101 includes an insulating substrate 2, a plurality of semiconductor elements 1, and a metal lead electrode 4.

The insulating substrate 2 includes an insulating base material 2b, a circuit pattern 2a formed on the upper surface of the insulating base material 2b, and a circuit pattern 2c formed on the lower surface of the insulating base material 2b. The insulating base material 2b is made of ceramic with excellent thermal conductivity, such as aluminum nitride or silicon nitride, or resin. The circuit patterns 2a and 2c are made of a material with excellent electrical conductivity and thermal conductivity, such as an aluminum alloy or copper. The upper surface of the circuit pattern 2a constitutes the upper surface of the insulating substrate 2. Although not illustrated, the circuit pattern 2c of the insulating substrate 2 may be bonded to a base plate made of an aluminum alloy or copper with excellent thermal conductivity using a bonding material such as solder or soft solder.

A plurality of semiconductor elements 1 are bonded to a mounting area 2a1 on the upper surface of the circuit pattern 2a of the insulating substrate 2 using a bonding material 3b such as solder. Note that areas on the upper surface of the circuit pattern 2a of the insulating substrate 2 where the plurality of semiconductor elements 1 are not mounted are referred to as a non-mounting area 2a2. That is, the upper surface of the circuit pattern 2a has the mounting area 2a1 and the non-mounting area 2a2.

Although IGBTs, diodes, or reverse conducting IGBTs made of silicon (Si) are often used for the semiconductor element 1, MOSFETs or Schottky diodes made of materials with a larger band gap than Si such as silicon carbide (SiC) or gallium nitride (GaN) may also be used. Although three semiconductor elements 1 are illustrated in FIG. 1, the number of semiconductor elements 1 mounted on the circuit pattern 2a is not 20 limited thereto, and can be determined as appropriate depending on the application of the semiconductor device 101.

Although not illustrated, a front surface electrode for metal bonding with a bonding material 3a such as solder is formed on the upper surface of each semiconductor element 1 by Ni—Au plating or the like. The upper surface of each semiconductor element 1 on which the front surface electrode is formed is bonded to a metal lead electrode 4 using the bonding material 3a such as solder. Although bonded to the upper surface of the semiconductor elements 1 in FIG. 1, the metal lead electrode 4 may be bonded to the circuit pattern 2a in addition to this.

The non-mounting area 2a2 of the circuit pattern 2a is provided with a plurality of protrusions 2d that protrude upward from the mounting area 2a1. An end surface of the protrusion 2d is higher than the upper surface of each semiconductor element 1 mounted in the mounting area 2a1 of the circuit pattern 2a. Further, the end surface of the protrusion 2d is set at a height that can secure a necessary insulation distance between the end surface and the metal lead electrode 4. Although two protrusions 2d are illustrated in FIG. 1, the number of protrusions 2d is not limited thereto. The protrusion 2d is provided with a necessary insulation distance between the protrusion 2d per se and the outer periphery of the semiconductor element 1. The metal lead electrode 4 may be bent upward or laterally at a position corresponding to the protrusion 2d to secure the insulating distance between the metal lead electrode 4 and the protrusion 2d.

In the manufacturing processes of the semiconductor device 101, which will be described later, the metal lead electrode 4 is electrically connected to an external output terminal, and the plurality of semiconductor elements 1 are electrically connected to each other. However, the semiconductor device 101 is illustrated in a simplified manner in FIG. 1, and wires such as signal lines, signal terminals, external output terminals, sealing resin materials, and the like are omitted from illustration in FIG. 1.

### A-2. Manufacturing Processes

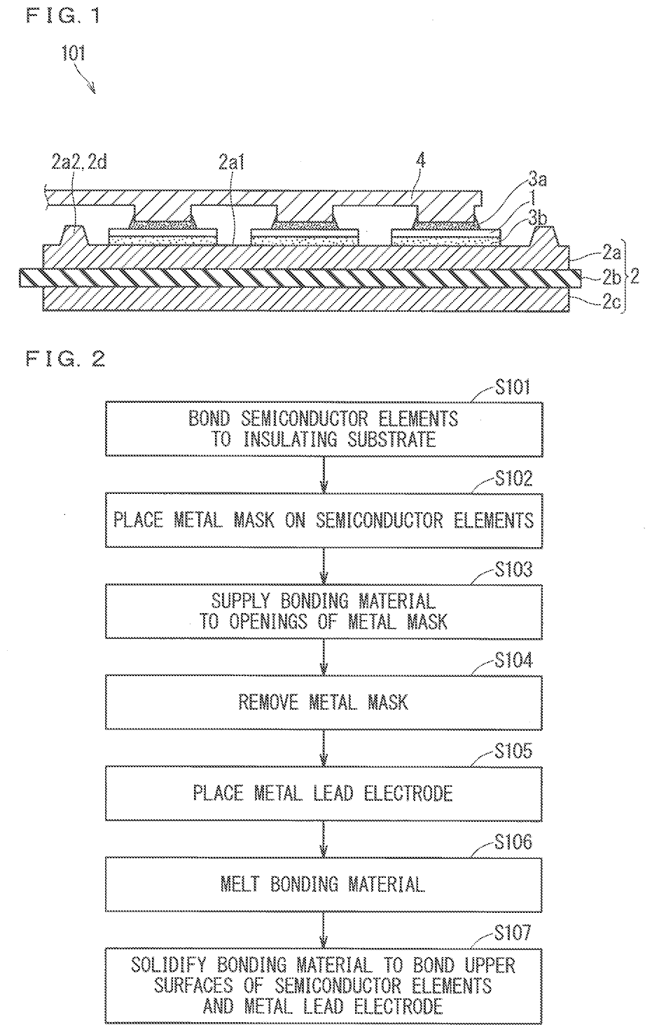

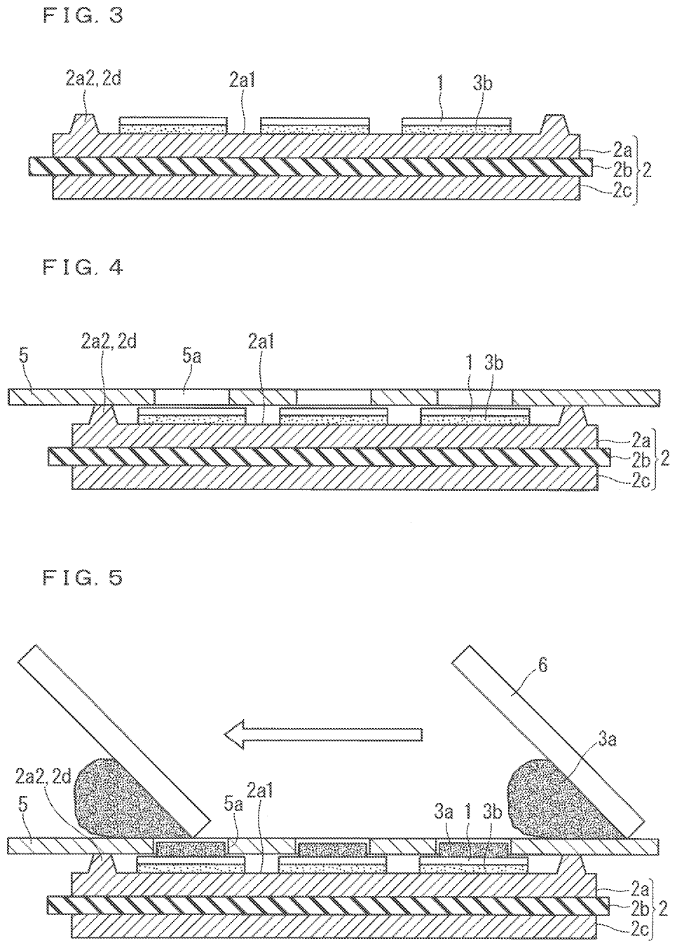

FIG. 2 is a flowchart illustrating manufacturing processes of the semiconductor device 101. FIGS. 3 to 7 are cross-sectional views illustrating intermediate states of manufacturing of the semiconductor device 101. Hereinafter, the manufacturing processes of the semiconductor device 101 will be described below with reference to FIGS. 2 to 7.

First, as illustrated in FIG. 3, the plurality of semiconductor elements 1 are bonded to the insulating substrate 2 (Step S101). Specifically, the plurality of semiconductor elements I are bonded to the mounting area 2a1 of the circuit pattern 2a of the insulating substrate 2 using the bonding material 3b. Typically, solder is used as the bonding material 3b. The bonding material 3b may be a pre-formed material such as plate solder, or may be a solder paste or other soft solder. The paste-like bonding material 3b may be applied using screen printing, dispensing, or the like. The plurality of semiconductor elements 1 are bonded onto the circuit pattern 2a by heating the bonding material 3b on the circuit pattern 2a to a temperature exceeding its melting point.

Next, as illustrated in FIG. 4, a metal mask 5 is placed on the plurality of semiconductor elements 1 bonded to the insulating substrate 2 (Step S102 in FIG. 2). As mentioned above, the end surface of the protrusion 2d is higher than the upper surface of each semiconductor element 1 mounted in the mounting area 2a1, so the metal mask 5 comes into contact with the end surface of the protrusion 2d of the circuit pattern 2a, and the metal mask 5 does not contact the upper surfaces of the semiconductor elements 1. That is, clearances exist between the metal mask 5 and the upper surfaces of the semiconductor elements 1. The metal mask 5 is typically made of a rigid metal material with excellent wear resistance, such as SUS. An opening 5a for supplying the bonding material 3a to the upper surface of each semiconductor element 1 is provided in a region of the metal mask 5 corresponding to each semiconductor element 1. The region of the metal mask 5 corresponding to each semiconductor element 1 is the region of the metal mask 5 that overlaps each semiconductor element 1 in plan view. The area of the opening 5a is set to be greater than or equal to the area of the bonding material 3a, taking into account the area required for the bonding material 3a between each semiconductor element 1 and the metal lead electrode 4. And, the thickness of the metal mask 5 is designed in consideration of the volume required for the bonding material 3a between the semiconductor elements 1 and the metal lead electrode 4, and is typically 0.1 mm or more and less than 0.2 mm.

Then, the bonding material 3a such as paste solder is supplied to the openings 5a of the metal mask 5 (Step S103 in FIG. 2). Specifically, as illustrated in FIG. 5, the bonding material 3a is supplied onto the metal mask 5, and the bonding material 3a is rubbed against the openings 5a as many times as necessary using a squeegee 6 made of SUS or urethane to fill the openings 5a. As mentioned above, the existence of the clearances between the metal mask 5 and the upper surfaces of the semiconductor elements 1 allows the bonding material 3a to be supplied to the upper surfaces of the semiconductor elements 1, that is, the bonding surfaces to be bonded with the metal lead electrode 4 without the semiconductor elements 1 coming into contact with the metal mask 5. Note that the bonding material 3a could possibly flow from the openings 5a of the metal mask 5 and leaks between the upper surfaces of the semiconductor elements 1 and the metal mask 5. However, adjusting the leakage amount of the bonding material 3a is enabled by adjusting printing conditions such as the printing speed, printing angle, and printing pressure of the squeegee 6 according to the viscosity or thixotropy of the bonding material 3a.

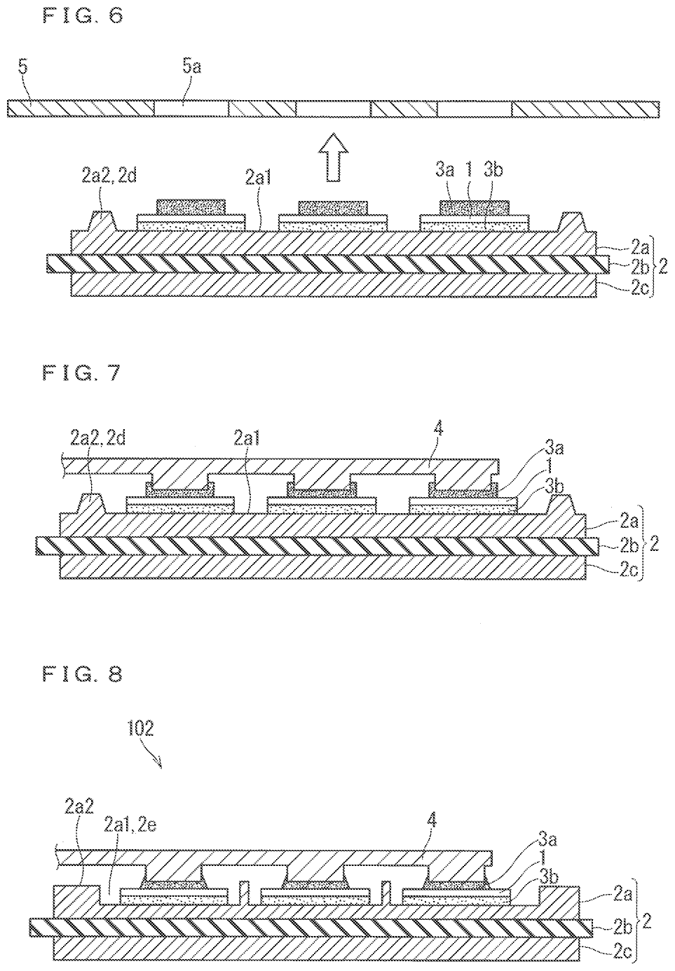

Next, as illustrated in FIG. 6, the metal mask 5 is removed from the insulating substrate 2 (Step S104 in FIG. 2). At the point of removing the metal mask 5 from the insulating substrate 2, when the bonding material 3a sticks to a wall surface of the opening 5a of the metal mask 5 due to its viscosity, only an area smaller than the area of the opening 5a remains on the bonding surface of the semiconductor element 1. As countermeasures, commonly known methods include reducing the shear force acting on the wall surface of the opening 5a by adjusting the speed and acceleration of removing the metal mask 5 from the insulating substrate 2 in multiple stages, reducing the wall surface roughness of the opening 5a, and coating the wall surface of the opening 5a with a resin material or the like.

Thereafter, as illustrated in FIG. 7, the metal lead electrode 4 is placed on the bonding material 3a supplied onto the semiconductor elements 1 (Step S105 in FIG. 2). The metal lead electrode 4 is held by the thixotropic properties of the bonding material 3a. The end portion of the metal lead electrode 4 may be bonded to an external electrode or the like. Alternatively, the metal lead electrode 4 per se may be extended to serve as an external electrode. Although in FIG. 7, the metal lead electrode 4 is bonded to the semiconductor elements 1, in addition to this, the metal lead electrode 4 may be bonded to the circuit pattern 2a of the insulating substrate 2 using another bonding material. Also, although one metal lead electrode 4 is illustrated in FIG. 7, a plurality of metal lead electrodes 4 may be bonded to the semiconductor elements 1 or the circuit pattern 2a using different bonding materials.

Next, the bonding material 3a is heated with a heating device such as a reflow oven, and is melted by raising the temperature to a temperature higher than its melting point (Step S106 in FIG. 2). For example, if the melting point of the bonding material 3a is 220 degrees, it is heated at 220° C. or higher for 5 minutes using a reflow tank that reaches a maximum temperature of 270 degrees. In this step, the bonding material 3b between the semiconductor elements 1 and the insulating substrate 2 may be re-melted. Alternatively, remelting of the bonding material 3b may be avoided by using a bonding material having a higher melting point than the bonding material 3a.

Thereafter, the bonding material 3a is cooled and solidified, thereby completing the bonding between the upper surface of the semiconductor elements 1 and the metal lead electrode 4. Thereafter, the semiconductor device 101 illustrated in FIG. 1 is completed through a circuit forming process using wire bonding or the like, a resin sealing process, and a characteristic testing process.

### A-3. Effect

In the semiconductor device 101 according to Embodiment 1, the upper surface of the insulating substrate 2 has the mounting area 2a1 where the plurality of semiconductor elements 1 are mounted, and the non-mounting area 2a2 which protrudes upward from the mounting area 2a1 and where no plurality of semiconductor elements 1 are mounted. The difference in height between the mounting area 2a1 and the non-mounting area 2a2 is greater than or equal to the thickness of each semiconductor element 1. The semiconductor device 101 includes the metal lead electrode 4 bonded to the upper surface of each semiconductor element 1 with the bonding material 3b.

According to the above configuration, the metal mask 5 used to collectively supply the bonding material 3a to the upper surface of each semiconductor element 1 comes into contact with the mounting area 2a1 on the upper surface of the insulating substrate 2, and the metal mask 5 does not come into contact with the upper surface of each semiconductor element 1 mounted in the mounting area 2a1. Accordingly, collective supply of the bonding material 3a to the plurality of semiconductor elements 1 by screen printing is enabled without damaging the semiconductor elements 1. Screen printing allows the bonding material 3a to be supplied to the plurality of semiconductor elements 1 in a shorter time than dispensing application. Therefore, the semiconductor device 101 with a stable long life can be manufactured with high productivity.

A method of manufacturing the semiconductor device 101 of Embodiment 1 includes (a) preparing the plurality of semiconductor elements 1 and the insulating substrate 2 having the mounting area 2al and the non-mounting area 2a2 protruding upward from the mounting area 2a1 on the upper surface thereof, (b) mounting each semiconductor element 1 on the mounting area 2a1 on the upper surface of the insulating substrate 2, (c) after each semiconductor element 1 is mounted, placing the metal mask 5 having the opening 5a at the position corresponding to each semiconductor element 1 on the upper surface of the insulating substrate 2 with contacting the non-mounting area 2a2 on the upper surface of the insulating substrate 2, (d) supplying the bonding material 3a to the upper surface of each semiconductor element 1 through the opening of the metal mask 5, (e) removing the metal mask 5, and (f) after removing the metal mask 5, bonding the metal lead electrode 4 to the bonding material 3a on the upper surface of each semiconductor element 1. And the difference in height between the mounting area 2a1 and the non-mounting area 2a2 is greater than or equal to the thickness of each semiconductor element 1. According to the above configuration, collective supply of the bonding material 3a to the plurality of semiconductor elements 1 by screen printing is enabled without damaging the semiconductor elements 1 because the metal mask 5 does not come into contact with each semiconductor element 1.

### B. Embodiment 2

### B-1. Configuration

FIG. 8 is a cross-sectional view of a semiconductor device 102 according to Embodiment 2. The difference from semiconductor device 101 according to Embodiment 1 is in that the semiconductor device 102 includes a concave portion 2e instead of the protrusion 2d on the upper surface of the circuit pattern 2a. The semiconductor element 1 is mounted, in the state of being mounted in the concave portion 2e, with the upper surface thereof must be lower than the upper surface other than the concave portion 2e of the circuit pattern 2a. The depth of the concave portion 2e is designed taking this factor into consideration. A necessary insulation distance is provided between the side surfaces of the concave portion 2e and the outer periphery of the semiconductor element 1. The configuration of semiconductor device 102 other than the above is similar to the semiconductor device 101.

A method of manufacturing the semiconductor device 102 is the same as the method of manufacturing the semiconductor device 101 except for the upper surface shape of the circuit pattern 2a.

### B-2. Effect

That is, in Embodiment 2, the bottom surface of the concave portion 2e of the circuit pattern 2a becomes the mounting area 2a1, and the upper surface of the circuit pattern 2a other than the concave portion 2e becomes the non-mounting area 2a2.

According to the above configuration, the metal mask 5 used to collectively supply the bonding material 3a to the upper surface of each semiconductor element 1 comes into contact with the upper surface other than the concave portions 2e of the circuit pattern 2a. Accordingly, collective supply of the bonding material 3a to the plurality of semiconductor elements 1 by screen printing is enabled without damaging the semiconductor elements 1. Screen printing allows the bonding material 3a to be supplied to the plurality of semiconductor elements 1 in a shorter time than dispensing application. Therefore, the semiconductor device 102 with a stable long life can be manufactured with high productivity.

In addition, when providing bonding portions with the metal lead electrode 4 on the circuit pattern 2a, the metal mask 5 is in close contact with the upper surface of the non-mounting area 2a2 of the circuit pattern 2a; therefore, the bonding material can be supplied to the circuit pattern 2a simply by providing the openings 5a in the metal mask 5.

### C. Embodiment 3

### C-1. Configuration

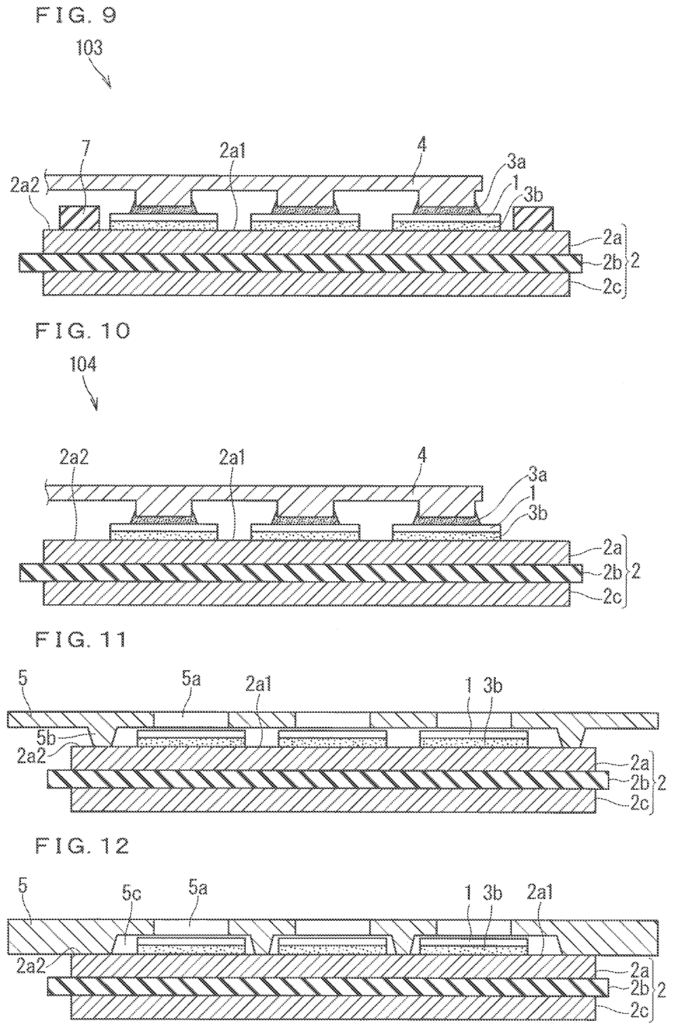

FIG. 9 is a cross-sectional view of a semiconductor device 103 according to Embodiment 3. The difference from semiconductor device 101 according to Embodiment 1 is in that the semiconductor device 103 includes a plurality of insulating members 7 provided on the upper surface of the circuit pattern 2a instead of the circuit pattern 2a not having the plurality of protrusions 2d. The upper surface of each insulating member 7 is higher than the upper surface of each semiconductor element 1 mounted in the mounting area 2a1. That is, each insulating member 7 is thicker than each semiconductor element 1. The material of the insulating members 7 may be a resin having necessary insulation performance such as Polyphenylenesulfide (PPS), or may be ceramic. The planar shape of the insulating members 7 may have a frame shape. Each insulating member 7 may consist of a combination of a plurality of spaced apart members.

The insulating member 7 may partially underpin the metal lead electrode 4 from below. There is no need to secure an insulating distance between the insulating member 7 and the semiconductor element 1. Therefore, the insulating members 7 may be used for positioning the semiconductor elements 1.

The method of manufacturing the semiconductor device 103 is the same as the method of manufacturing the semiconductor device 101 except for the shape of the circuit pattern 2a and the insulating members 7.

### C-2. Effect

That is, in Embodiment 3, the upper surface of the insulating members 7 provided on the upper surface of the circuit pattern 2a becomes the non-mounting area 2a2, and, of the upper surface of the circuit pattern 2a other than a region where no insulating members 7 are provided becomes the mounting area 2a1.

According to the above configuration, the metal mask 5 used to collectively supply the bonding material 3a to the upper surface of each semiconductor element 1 comes into contact with the insulating members 7 and does not come into contact with the semiconductor elements 1. Accordingly, collective supply of the bonding material 3a to the plurality of semiconductor elements 1 by screen printing is enabled without damaging the semiconductor elements 1. Screen printing allows the bonding material 3a to be supplied to the plurality of semiconductor elements 1 in a shorter time than dispensing application. Therefore, the semiconductor device 103 with a stable long life can be manufactured with high productivity.

Further, there is no need to secure an insulating distance between the insulating member 7 and the semiconductor element 1, enabling to downsize the semiconductor device 103. Note that in the case of the semiconductor device 101 according to Embodiment 1, a jig for positioning a semiconductor element 1 is additionally required when the semiconductor element 1 is bonded to the insulating substrate 2 using the plate solder bonding material 3b. However, in the semiconductor device 103, the semiconductor element 1 can be positioned using the insulating member 7, so the process can be simplified by omitting the jig. Further, depending on its shape, the insulating member 7 can also be used for positioning the metal lead electrode 4 in the height direction.

### D. Embodiment 4

### D-1. Configuration

FIG. 10 is a cross-sectional view of a semiconductor device 104 according to Embodiment 4. The difference from semiconductor device 101 according to Embodiment 1 is in that, in the semiconductor device 104, the circuit pattern 2 does not have the protrusions 2d.

### D-2. Manufacturing Processes

The manufacturing processes of the semiconductor device 104 differs from the manufacturing processes of the semiconductor device 101 only in the shape of the metal mask 5 used to supply the bonding material 3b to the upper surfaces of the plurality of semiconductor elements 1.

FIG. 11 is a cross-sectional view illustrating a state in which the metal mask 5 is placed on the semiconductor elements 1 in a manufacturing process of the semiconductor device 104. A convex portion 5b is provided on the lower surface of the metal mask 5 at a position corresponding to the non-mounting area 2a2 of the circuit pattern 2a. The convex portion 5b is higher than the semiconductor element 1 and the bonding material 3b combined.

The lower surface of the metal mask other than the convex portion 5b is a first region that does not contact the upper surface of the circuit pattern 2a and the upper surface of each semiconductor element 1. Further, the end surface of the convex portion 5b is a second region that contacts the upper surface of the circuit pattern 2a. In other words, the lower surface of the metal mask 5 has a first region and a second region protruding downward from the first region. Also, the metal mask 5 has the openings 5a in the first region, and the opening 5a overlap each semiconductor element 1, and is placed on the upper surface of the insulating substrate 2 such that the second region is in contact with the upper surface of the circuit pattern 2a. FIG. 11 illustrates this state.

The convex portion 5b may be formed by half-etching the lower surface of the metal mask 5 other than the portion where the convex portion 5b is to be formed. The height of the convex portion 5b is greater than or equal to the thickness of each semiconductor element 1. In other words, the difference in height between the first region and the second region is greater than or equal to the thickness of each semiconductor element 1. Therefore, the end surface of the convex portion 5b of the metal mask 5 comes into contact with the upper surface of the circuit pattern 2a, so that the upper surfaces of the semiconductor elements 1 do not come into contact with the metal mask 5.

### D-3. Modification

As illustrated in FIG. 12, a concave portion 5c may be provided on the lower surface of the metal mask 5 at a position overlapping each semiconductor element 1 instead of the convex portion 5b. That is, the bottom surface of the concave portion 5c becomes the first region, and the lower surface of the metal mask 5 other than the concave portion 5c becomes the second region. The depth of the concave portion 5e is greater than or equal to the thickness of each semiconductor element 1. In other words, the difference in height between the first region and the second region is greater than or equal to the thickness of each semiconductor element 1. Therefore, the lower surface of the metal mask 5 other than the concave portions 5c comes into contact with the upper surface of the circuit pattern 2a, so that the upper surfaces of the semiconductor elements 1 do not come into contact with the bottom surfaces of the concave portions 5c.

### D-4. Effect

A method of manufacturing the semiconductor device 104 of Embodiment 4 includes (a) preparing the plurality of semiconductor elements 1 and the insulating substrate 2, (b) mounting each semiconductor element 1 on the upper surface of the insulating substrate 2, (c) placing the metal mask 5 having, on its lower surface, the first regions and the second regions protruding downward from the first regions, and having the openings 5a in the first regions, on the upper surface of the insulating substrate 2, such that the second regions come into contact with the upper surface of the insulating substrate 2, and the opening 5a overlaps each semiconductor element 1 mounted on the insulating substrate 2, (d) supplying the bonding material 3a to the upper surface of each semiconductor element I through the opening 5a of the metal mask 5, (e) removing the metal mask 5, and (f) after removing the metal mask 5, bonding the metal lead electrode 4 to the bonding material 3a on the upper surface of each semiconductor element 1. Here, the difference in height between the first region and the second region is greater than or equal to the thickness of each semiconductor element 1.

Accordingly, the second regions of the lower surface of metal mask 5 come into contact with the insulating substrate 2; thereby, the upper surface of each semiconductor element 1 does not come into contact with the first region of the lower surface of metal mask 5. Accordingly, collective supply of the bonding material 3a to the plurality of semiconductor elements 1 by screen printing is enabled without damaging the semiconductor elements 1. Screen printing allows the bonding material 3a to be supplied to the plurality of semiconductor elements 1 in a shorter time than dispensing application. Therefore, the semiconductor device 104 with a stable long life can be manufactured with high productivity.

Furthermore, unlike Embodiments 1 and 2, there are no restrictions on the shape of the circuit pattern 2a, so the insulating substrate 2 can be easily designed.

It should be noted that Embodiments can be arbitrarily combined and can be appropriately modified or omitted. The forgoing description is in all aspects illustrative. It is therefore understood that numerous undescribed modifications and variations can be devised.

### EXPLANATION OF REFERENCE SIGNS

1 semiconductor element, 2 insulating substrate, 2a circuit pattern, 2a1 mounting area, 2a2 non-mounting area, 2b insulating base material, 2c circuit pattern, 2d protrusion, 2e concave portion, 3a, 3b bonding material, 4 metal lead electrode, 5 metal mask, 5a opening, 5b convex portion, 5c concave portion, 6 squeegee, 7 insulating material, 101 to 104 semiconductor device.

1. A semiconductor device comprising:
a plurality of semiconductor elements;
an insulating substrate having, on its upper surface, a mounting area where the plurality of semiconductor elements are mounted and a non-mounting area protruding upward from the mounting area and where the plurality of semiconductor elements are not mounted; and
a metal lead electrode bonded to an upper surface of each of the semiconductor elements with a bonding material, wherein
a difference in height between the mounting area and the non-mounting area is greater than or equal to a thickness of each of the semiconductor elements.

2. The semiconductor device according to claim 1, wherein
the insulating substrate includes
an insulating base material, and
a circuit pattern provided on the insulating base material,
an upper surface of the circuit pattern has a convex portion,
an end surface of the convex portion is the non-mounting area, and
the upper surface of the circuit pattern other than the convex portion is the mounting area.

3. The semiconductor device according to claim 1, wherein
the insulating substrate includes
an insulating base material, and
a circuit pattern provided on the insulating base material,
an upper surface of the circuit pattern has a concave portion,
a bottom surface of the concave portion is the mounting area, and
the upper surface of the circuit pattern other than the concave portion is the non-mounting area.

4. The semiconductor device according to claim 1, wherein
the insulating substrate includes
an insulating base material,
a circuit pattern provided on the insulating base material, and
an insulating member provided on the upper surface of the circuit pattern,
an upper surface of the insulating member is the non-mounting area, and
a region of the upper surface of the circuit pattern where the insulating member is not provided is the mounting area.

5. A method of manufacturing a semiconductor device, comprising:
(a) preparing a plurality of semiconductor elements and an insulating substrate having a mounting area and a non-mounting area protruding upward from the mounting area on an upper surface thereof;
(b) mounting each of the semiconductor elements on the mounting area on the upper surface of the insulating substrate;
(c) after each of the semiconductor elements is mounted, placing a metal mask having an opening at a position corresponding to each of the semiconductor elements on the upper surface of the insulating substrate with contacting the non-mounting area on the upper surface of the insulating substrate;
(d) supplying a bonding material to an upper surface of each of the semiconductor element through the opening of the metal mask;
(e) removing the metal mask; and
(f) after removing the metal mask, bonding a metal lead electrode to the bonding material on the upper surface of each of the semiconductor elements, wherein
a difference in height between the mounting area and the non-mounting area is greater than or equal to a thickness of each of the semiconductor elements.

6. The method of manufacturing the semiconductor device according to claim 5, wherein
the insulating substrate includes
an insulating base material, and
a circuit pattern provided on the insulating base material,
an upper surface of the circuit pattern has a convex portion,
an end surface of the convex portion is the non-mounting area, and
the upper surface of the circuit pattern other than the convex portion is the mounting area.

7. The method of manufacturing the semiconductor device according to claim 5, wherein
the insulating substrate includes
an insulating base material, and
a circuit pattern provided on the insulating base material,
an upper surface of the circuit pattern has a concave portion,
the upper surface of the circuit pattern other than the concave portion is the mounting area, and
a bottom surface of the concave portion is the non-mounting area,

8. The method of manufacturing the semiconductor device according to claim 5, wherein
the insulating substrate includes
an insulating base material,
a circuit pattern provided on the insulating base material, and
an insulating member provided on the upper surface of the circuit pattern,
an upper surface of the insulating member is the non-mounting area, and
a region of the upper surface of the circuit pattern where the insulating member is not provided is the mounting area.

9. A method of manufacturing a semiconductor device, comprising:
(a) preparing a plurality of semiconductor elements and an insulating substrate;
(b) mounting each of the semiconductor elements on an upper surface of the insulating substrate;
(c) placing a metal mask having, on its lower surface, first regions and second regions protruding downward from the first regions, and having openings in the first regions, on the upper surface of the insulating substrate, such that the second regions come into contact with the upper surface of the insulating substrate, and the opening overlaps each of the semiconductor elements mounted on the insulating substrate;
(d) supplying a bonding material to the upper surface of each of the semiconductor elements through the opening of the metal mask;
(e) removing the metal mask; and
(f) after removing the metal mask, bonding the metal lead electrode to the bonding material on the upper surface of each of the semiconductor elements, wherein a difference in height between the first region and the second region is greater than or equal to a thickness of each of the semiconductor elements.

10. The method of manufacturing the semiconductor device according to claim 9, wherein
the metal mask has a convex portion on a lower surface thereof,
an end surface of the convex portion is the second region, and
the lower surface of the metal mask other than the convex portion is the first region.

11. The method of manufacturing the semiconductor device according to claim 9, wherein
the metal mask has a concave portion on a lower surface thereof,
a bottom surface of the concave portion is the first region, and
the lower surface of the metal mask other than the concave portion is the second region.
